(19) United States
(12) Patent Application Publication
(10) Pub. No.: US 2002/0034595 A1
(43) Pub. Date: Mar. 21, 2002

(54) Substrate processing equipment and method and covering member for use therein

(76) Inventor: Kouji Tometsuka, Tokyo (JP)

Correspondence Address: BACON & THOMAS, PLLC, 625 SLATERS LANE, FOURTH FLOOR, ALEXANDRIA, VA, 22314

(21) Appl. No.: 09/954,187

(22) Filed: Sep. 18, 2001

(30) Foreign Application Priority Data
Sep. 19, 2000 (JP) 2000-283254
May 10, 2001 (JP) 2001-139888

(51) Int. Cl. C23F 1/00; B44C 1/22; C23C 16/00; H01L 21/302; C23F 1/02; C03C 25/68

(52) U.S. Cl. 427/569; 156/345; 118/719; 438/710; 438/758; 216/63

(57) ABSTRACT

A wafer may be protected from being contaminated by contaminants and cooled at the same time. In a multi chamber CVD equipment, while a wafer arm 55 of a transfer robot transfers a high-temperature wafer 1 from a CVD chamber to a cooling chamber, the wafer 1 is covered with a cooling and guarding plate 60. The cooling and guarding plate 60 has an abutting ring 61 abutted along the perimeter of an upper surface of the wafer 1, a support ring 62 with the shape of a cylinder having a small height installed on the abutting ring 61, a covering plate 63 with the shape of a disc formed on the support ring 62, a plurality of radiating fins 64 and a set of handles 65 projected along both sides of the plurality of radiating fins 64, wherein the cooling and guarding plate arm 56 is inserted underneath the handles 65.

### FIELD OF THE INVENTION

The present invention relates to a substrate processing equipment and method and a covering member for use therein; and, more particularly, to a substrate processing equipment and method and a covering member capable of being effectively used during a transfer process of a substrate in a multi chamber chemical vapor deposition (CVD) equipment by which a film of SiO₂ or SiNₓ or a metal film is formed on a silicon wafer.

### BACKGROUND OF THE INVENTION

A multi chamber CVD equipment is used to form a film of SiO₂ or SiNₓ or a metal film on a wafer. Such multi chamber CVD equipment may include two CVD chambers for forming a film of SiO₂ or SiNₓ or a metal film on the wafer, two cooling chambers for cooling the wafer and two cassette chambers for receiving cassettes having a plurality of wafers, wherein the chambers are arranged around a transfer chamber equipped with a transfer robot for transferring wafers in and out of the chambers.

In addition, it has been contemplated to install an additional cleaning chamber in such multi chamber CVD equipment so that the wafers may be pre-cleaned before being taken in the CVD chamber.

Since, however, the wafer is transferred at a higher temperature from a CVD chamber to a cooling chamber, floating contaminants may be attracted to the surface of the wafer to react therewith or the rapid temperature change may result in a warping of the wafer Even in the multi chamber CVD equipment equipped with the cleaning chamber in which a wafer is processed in a CVD chamber after being cleaned in the cleaning chamber, the surface of the cleaned wafer remains uncovered during transferring. Thereafter, it is possible that the floating contaminants may be attracted to the surface of the wafer to contaminate it.

### SUMMARY OF THE INVENTION

It is, therefore, an object of the present invention to provide a substrate processing equipment and method capable of preventing the processing chambers from being contaminated by each other.

It is, therefore, anther object of the present invention to provide a substrate processing equipment and method capable of quickly cooling the substrate.

It is, therefore, still another object of the present invention to provide a substrate processing equipment and method capable of preventing the substrate from being contaminated during the transfer process thereof. In accordance with a preferred embodiment of the present invention, there is provided a substrate processing equipment comprising:

a substrate; and

a covering member for covering a surface of the substrate,

wherein the substrate is transferred while the surface of the substrate is covered with the covering member.

In accordance with the present invention, the surface of the substrate is covered with the covering member during the transfer process of the substrate so that the surface of the substrate may be prevented from attracting contaminants and the processing chambers may be protected from being contaminated by each other. Since, in addition, the substrate can be efficiently cooled by the covering member, the substrate may be protected from being warped and also further prevented from reacting with contaminants that will be rarely attracted thereto.

### BRIEF DESCRIPTION OF THE DRAWINGS

The above and other objects and features of the present invention will become apparent from the following description of preferred embodiments given in conjunction with the accompanying drawings, in which:

FIG. 1 represents a plan view for illustrating a multi chamber CVD equipment in accordance with a first preferred embodiment of the present invention;

FIG. 2 shows a front cross sectional view of a CVD apparatus of the CVD equipment shown in FIG. 1;

FIG. 3 describes a front cross sectional view a cooling apparatus of the CVD equipment shown in FIG. 1;

FIG. 4A provides a front view for illustrating a transfer robot of the CVD equipment shown in FIG. 1;

FIG. 4B presents a plan view for illustrating the transfer robot with a portion of the transfer robot extended;

FIG. 5A depicts a plan view for illustrating a cooling and guarding plate;

FIG. 5B sets forth a cutaway front view for illustrating the cooling and guarding plate;

FIG. 5C describes a side view for illustrating the cooling and guarding plate;

FIG. 6A provides a cutaway front view for illustrating a transfer operation of a wafer arm;

FIG. 6B represents a cutaway front view for illustrating a transfer operation of a cooling and guarding plate arm;

FIG. 7 presents a plan view of a multi chamber CVD equipment in accordance with a second preferred embodiment of the present invention; and

FIGS. 8A to 8D are cutaway front views for illustrating various cooling and guarding plates in accordance with the present invention.

### DETAILED DESCRIPTION OF THE PREFERRED EMBODIMENTS

The semiconductor processing equipment in accordance with a first preferred embodiment of the present invention is of a multi chamber type CVD equipment, which is used in depositing on a wafer an insulating film made of silicon oxide or silicon nitride or a metal film made of Ta₂O₅ or Ru.

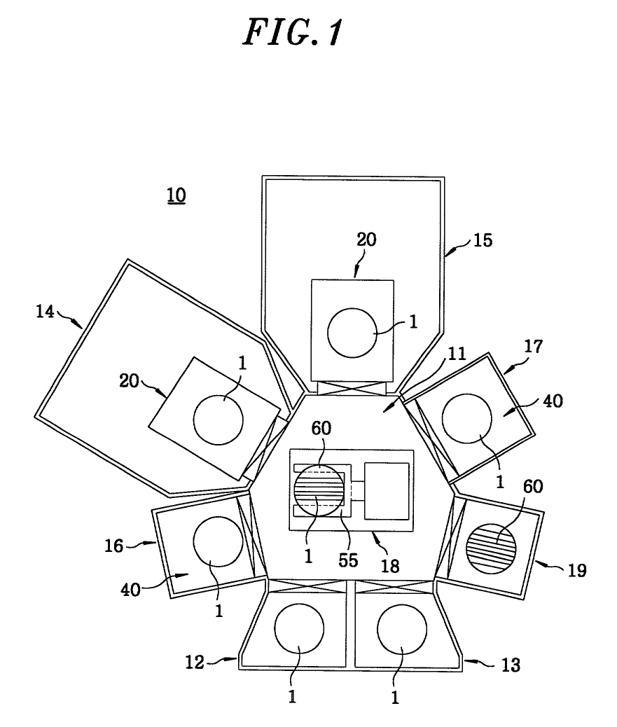

As shown in FIG. 1, the multi chamber CVD equipment 10 in accordance with the present invention includes a transfer chamber 11 of a polygonal prism, e.g., a hexagonal prism whose base is a hexagon. A first cassette chamber 12, a second cassette chamber 13, a first CVD chamber 14, a second CVD chamber 15, a first cooling chamber 16 and a second cooling chamber 17 are arranged on side surfaces of the transfer chamber 11. A transfer robot 18 is installed within the transfer chamber 11 as a transfer device for taking wafers 1 in and out of the chambers 12 to 17. A temporary holding chamber 19 is arranged between the second cassette chamber 13 and the second cooling chamber 17 in order to temporarily hold one or more cooling and guarding plates 60 which will be illustrated hereinafter.

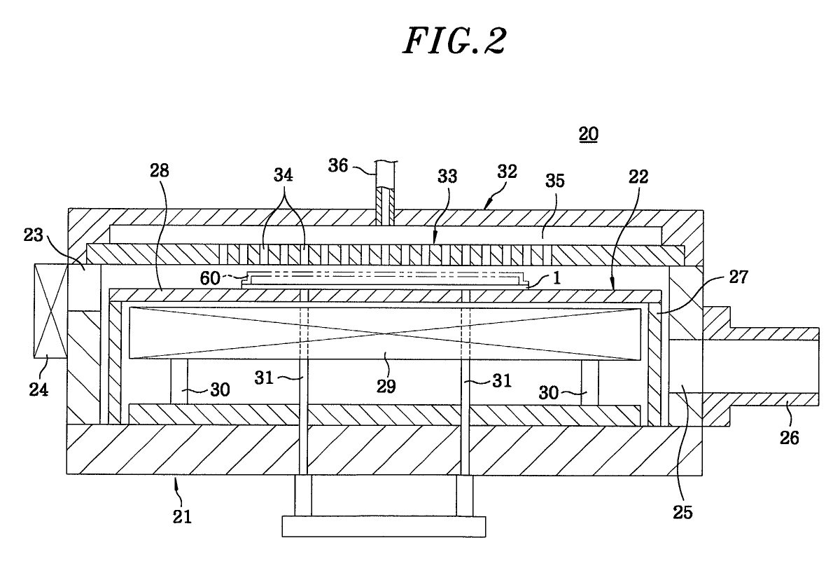

A cold wall type single wafer CVD apparatus (hereinafter called as a CVD apparatus) 20 shown in FIG. 2 is installed in both the first CVD chamber 14 and the second CVD chamber 15.

As shown in FIG. 2, the CVD apparatus 20 includes a process tube 21 of a cylindrical shape with an upper and a lower surface thereof closed. An inner space of the process tube 21 substantially forms a processing chamber 22. A wafer loading and unloading port 23 is horizontally elongated around a middle region of the sidewall of the process tube 21, so that the wafer loading and unloading port 23 can be used to transfer a wafer between the transfer chamber 11 and the processing chamber 22. A gate valve 24 is used to open and close the wafer loading and unloading port 23. An exhaust hole 25 to be connected with the processing chamber 22 is installed at the opposite side of the wafer loading and unloading port 23 of the process tube 21. The exhaust hole 25 is used to make a vacuum in the processing chamber 22 through an exhaust path 26 by an exhaust device (not shown) constituted by a vacuum pump or the like.

A holder 27 is concentrically installed on the floor wall of the process tube 21, wherein the holder 27 of a cylindrical shape and a susceptor 28 for concentrically supporting a sheet of wafer 1 is installed at an upper end of the holder 27. A heater 29 supported by a brace 30 is installed within the holder 27 so that the heater 29 may be controlled to heat the wafer 1 supported by the susceptor 28. Three vertically movable lift pins 31 are equispaced along a circle on the floor wall of the holder 27 (only two pins are shown in the drawing). The lift pins 31 may pass through the susceptor 28 so that the lift pins 31 may be controlled to lift the wafer 1 from the susceptor 28 horizontally.

A gas feeding head 32 for feeding a source gas, a purge gas or the like to the processing chamber 22 is mounted on an upper end of the processing chamber 22. A gas feeding plate 33 having a plurality of gas feeding holes 34 is horizontally installed at the gas feeding head 32. The cavity of the gas feeding head 32 forms a gas feeding path 35. A gas feeding line 36 is connected to the gas feeding path 35 in order to feed the source gas, the purge gas or the like. In other words, the gas fed through the gas feeding line 36 may be diffused at the gas feeding path 35 and then supplied toward the wafer 1 on the susceptor 28 through the gas feeding holes 34 of the gas feeding plate 33.

A cooling device 40 shown in FIG. 3 is installed in both the first cooling chamber 16 and the second cooling chamber 17 in accordance with the preferred embodiment of the present invention. Specifically, the cooling device 40 has a process tube 41 of a cylindrical shape with an upper and a lower surface thereof closed. An inner space of the process tube 41 substantially forms a processing chamber 42. A wafer loading and unloading port 43 is horizontally elongated around a middle region of the sidewall of the process tube 41, so that the wafer loading and unloading port 43 can be used to transfer a wafer between the transfer chamber 11 and the processing chamber 42. A gate valve 44 is used to open and close the wafer loading and unloading port 43. An exhaust hole 45 at the opposite side of the wafer loading and unloading port 43 of the process tube 41 is installed to be connected with the processing chamber 42. The exhaust hole 45 is used to make a vacuum in the processing chamber 42 through an exhaust path 46 by an exhaust device (not shown) constituted by a vacuum pump or the like.

A holder 47 is concentrically installed on the floor wall of the process tube 41, wherein the holder 47 of a cylindrical shape and a susceptor 48 for concentrically supporting a sheet of wafer 1 is installed at an upper end of the holder 47. Three vertically movable lift pins 49 are equispaced along a circle on the floor wall of the holder 47 (only two pins are shown in the drawings). The lift pins 49 can pass through the susceptor 48 so that the lift pins 49 may be controlled to lift the wafer 1 from the susceptor 48 horizontally. A cooling gas feeding line 50 for feeding a cooling gas, e.g., nitrogen gas is connected through the ceiling wall of the process tube 41.

The cooling device 40 is also installed in the temporary holding chamber 19. The nitrogen gas is used to prevent the cooling and guarding plate 60 from being contaminated, wherein the cooling and guarding plate 60 is temporarily held in the temporary holding chamber 19 as will be described later.

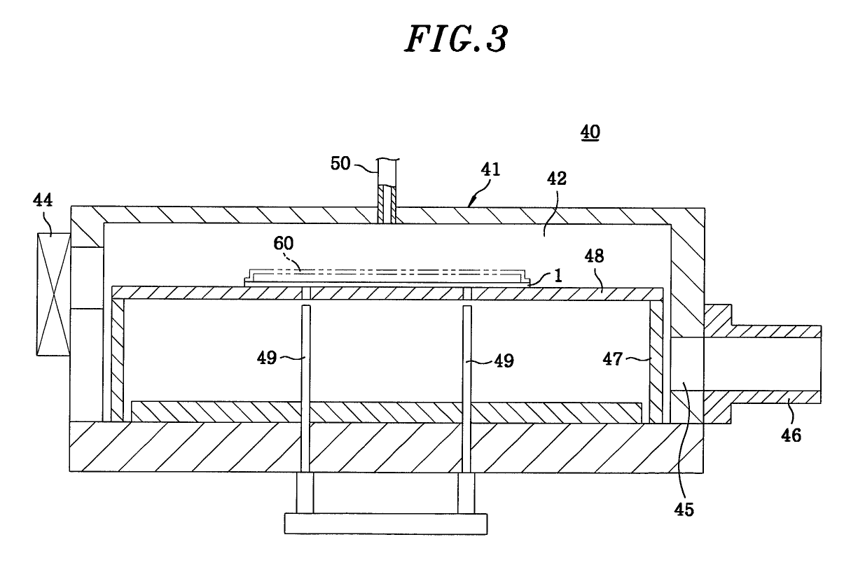

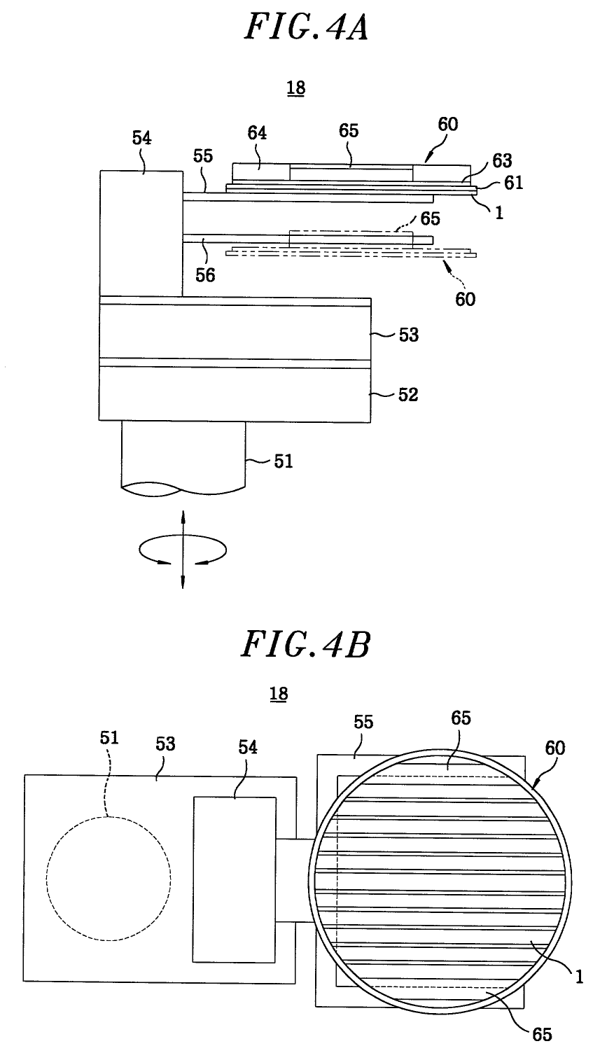

Referring to FIG. 4, there is illustrated the transfer robot 18. The transfer robot 18 may be elevated by an elevator (not shown). The transfer robot 18 has a spindle 51, which is rotated by a rotary actuator (not shown) and inserted in the transfer chamber 11 through the floor wall thereof. A first linear actuator 52 is horizontally supported at an inserting end of the spindle 51 and a second linear actuator 53 is mounted on the first linear actuator 52. The first linear actuator 52 is used to shift the second linear actuator 53 horizontally. A transfer die 54 is mounted on the second linear actuator 53 so that the second linear actuator 53 may be used to shift the transfer die 54 horizontally. A wafer arm 55 for supporting the wafer and a cooling and guarding plate arm 56 for supporting the cooling and guarding plate 60 as will be illustrated hereinafter are mounted at the transfer die 54, wherein the wafer arm 55 and the cooling and guarding plate arm 56 vertically separated by a predetermined distance are arranged horizontally. Both the wafer arm 55 and the cooling and guarding plate arm 56 have a shape of fork with two tines.

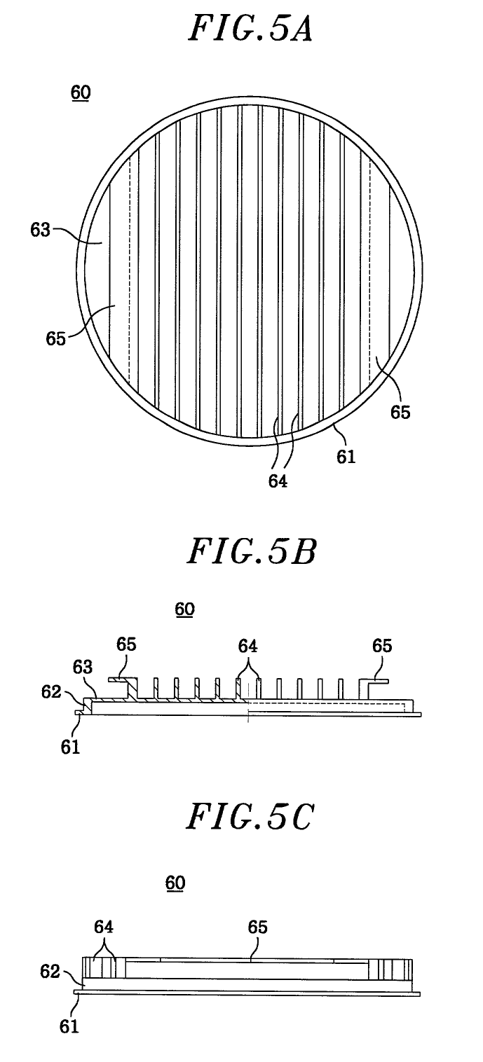

The multi chamber type CVD equipment 10 in accordance with the present invention is provided with the cooling and guarding plate 60 as covering members each for covering the surface of a wafer, i.e., the substrate, as shown in FIG. 5. A number of cooling and guarding plates 60 are prepared in the CVD equipment 10. The whole entity of each cooling and guarding plate 60 may be made of a heat resistant material, e.g., quartz and SiC, which imposes no adverse effect on the wafer 1, and preferably has a large heat capacity. As shown in FIG. 5, the cooling and guarding plate 60 has an abutting ring 61 with the shape of circular ring, wherein the outer diameter of the abutting ring 61 is substantially equal to that of the wafer 1 and the inner diameter of the abutting ring 61 is slightly larger than the outer diameter of an active region of the wafer 1. In other words, the contact width between the abutting ring 61 and the wafer 1 is set to be equal to or less than about 3 mm. A support ring 62 with the shape of a cylinder having a small height is concentrically and vertically formed on the abutting ring 61, wherein the inner diameter of the support ring 62 is equal to or larger than that of the abutting ring 61. The support ring 62 is coupled with the abutting ring 61. If only the wafer 1 is not contact with the support ring 62 and the abutting ring 61, the inner diameter of the support ring 62 may be smaller than that of the abutting ring 61. A covering plate 63 with the shape of a disc is formed on the support ring 62, wherein the outer diameter of the covering plate 63 is equal to that of the support ring 62. A plurality of radiating fins 64 running parallel to each other are projected on the covering plate 63, wherein each radiating fin 64 has a shape of rectangular plate. A set of handles 65 with the shape of angle bracket are projected along both sides of the plurality of radiating fins 64, wherein the radiating fins 64 and the handles 65 are arranged parallel with each other. The cooling and guarding plate arm 56 is inserted underneath the handles 65 so that the cooling and guarding plate arm 56 may be supported.

Hereinafter, there will be illustrated an operation of the CVD equipment 10 described above to demonstrate a process for manufacturing a film in a method for processing a substrate in accordance with the first embodiment of the present invention.

For example, a plurality of wafers on each of which a Ta₂O₅ film is to be deposited are provided to the first cassette chamber 12, wherein 25 sheets of wafers are preferably received in a cassette (not shown) to be used as a carrier jig. One of the wafers 1 received in the cassette of the first cassette chamber 12 is picked up by the transfer robot 18 and then taken out of the first cassette chamber 12 and transferred to the first CVD chamber 14. In other words, one wafer 1 among 25 sheets of wafers in the cassette is picked up by the wafer arm 55 of the transfer robot 18 and then transferred to the first CVD chamber 14.

The wafer 1 transferred to the first CVD chamber 14 by the transfer robot 18 is taken in the processing chamber 22 of the CVD apparatus 20 through the wafer loading and unloading port 23, and then the wafer 1 may be moved from the wafer arm 55 to the lift pins 31. The wafer 1 may be maintained horizontally by the susceptor 28 by lowering down the lift pins 31 having the wafer 1 thereon.

In the meantime, the processing chamber 22 in the CVD apparatus 20 is evacuated by the exhaust device (not shown) connected to the exhaust path 26 to a predetermined vacuum level (for example, about 50 to about 500 Pa). The heater 29 is then used to heat the wafer 1 supported by the susceptor 28 uniformly to a predetermined temperature (for example, about 1200° C.) or to have a predetermined temperature distribution across the wafer 1.

For example, a mixture gas of Ta(OC₂H₅)₅ and O₂ for serving as a source gas for forming a Ta₂O₅ film may be provided into the processing chamber 22 through the gas feeding line 36. The source gas received in the processing chamber 22 comes into contact with the surface of the wafer 1 supported on the susceptor 28 in the processing chamber 22 and then is exhausted through the exhaust hole 25. Since the source gas comes into contact with the wafer 1, the source gas may go through a chemical reaction with the wafer 1 due to a thermal energy and the Ta₂O₅ film may be deposited on the wafer 1 through the CVD reaction of the source gas.

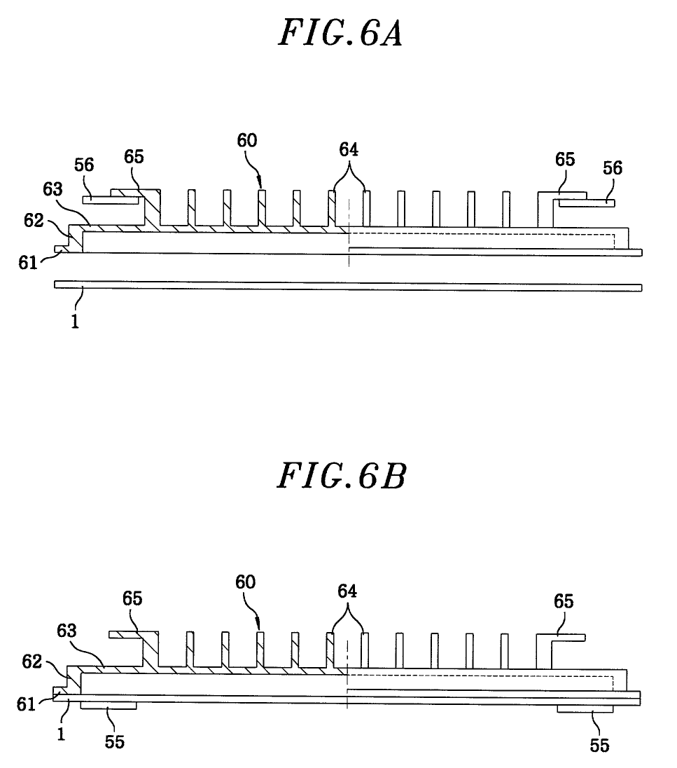

After a predetermined time elapses, the source gas is no longer provided through the gas feeding line 36 and the gate valve 24 is controlled to be open. The wafer 1, with a film deposited thereon, on the susceptor 28 is covered with the cooling and guarding plate 60 taken into the processing chamber 22 by the cooling and guarding plate arm 56 of the transfer robot 18. In other words, the transfer robot 18 makes the cooling and guarding plate arm 56 be inserted underneath a set of handles 65 of the cooling and guarding plate 60 temporarily stored in the temporary holding chamber 19 as shown in FIG. 6A and allows the spindle 51 of the transfer robot 18 to be operated so that the transfer robot 18 may pick up the cooling and guarding plate 60. The transfer robot 18 then transfers the cooling and guarding plate 60 picked up by the cooling and guarding plate arm 56 to the first CVD chamber 14, so that the cooling and guarding plate 60 may be taken in the processing chamber 22 in the CVD apparatus 20 of the first CVD chamber 14. After the transfer robot 18 places the cooling and guarding plate 60 on the wafer 1 as shown with a dotted line in FIG. 2, the transfer robot 18 retracts to remove the cooling and guarding plate arm 56 from the underneath of the handles 65. Thereafter, the wafer 1 with the cooling and guarding plate 60 covered is cooled in the processing chamber 22 to about 400° C. with a cooling rate of about 150° C./sec.

When the wafer 1 with the cooling and guarding plate 60 covered thereon is cooled to about 400° C., the lift pin 31 is controlled to be lifted so that the wafer 1 with the cooling and guarding plate 60 covered is lifted from the susceptor 28. After the wafer 1 is lifted, the transfer robot 18 allows the transfer die 54 to be forwarded by the second linear actuator 53, for example, as shown in FIG. 4B so that the wafer arm 55 may be inserted underneath the wafer 1. The transfer robot 18 allows the spindle 51 to be lifted upwards so that the wafer 1 with the cooling and guarding plate 60 covered may be received as shown in FIG. 6B.

After the wafer arm 55 receives the wafer 1, the transfer robot 18 allows the transfer die 54 to be retracted by the second linear actuator 53, for example, as shown in FIG. 4A so that the wafer 1 may be taken out of the processing chamber 22 of the CVD apparatus 20. Then, the transfer robot 18 transfers the wafer 1 taken out of the CVD apparatus 20 from the first CVD chamber 14 to the first cooling chamber 16 so that the wafer 1 may be taken in the processing chamber 42 of the cooling device 40 in the first cooling chamber 16. After the transfer robot 18 locates the wafer 1 with the cooling and guarding plate 60 covered thereon on the lift pins 49, the transfer robot 18 retreats to remove the wafer arm 55 from the underneath of the wafer 1 as shown as a dotted in FIG. 3. After the wafer arm 55 is removed from the underneath of the wafer 1, the transfer robot 18 is moved to the first cassette chamber 12 to transfer a next wafer 1 to the first CVD chamber 14.

After the wafer 1 is placed on the susceptor 48 by lowering the lift pins 49 in the first cooling chamber 16, the gate valve 44 is controlled to be closed and a high purity nitrogen gas is provided as a cooling gas from the cooling gas feeding line 50 to the processing chamber 42, so that the wafer 1 is cooled to the room temperature (about 25° C.) by a heat exchange with the nitrogen gas in the processing chamber 42.

After a predetermined time elapses, the nitrogen gas is no longer provided from the cooling gas feeding line 50 and the gate valve 44 is controlled to be open. The cooling and guarding plate 60 covering the wafer 1 cooled on the susceptor 28 is picked up and removed therefrom by the cooling and guarding plate arm 56 of transfer robot 18. In other words, the transfer robot 18 places the cooling and guarding plate arm 56 underneath the handles 65 of the cooling and guarding plate 60 and then operates the spindle 51 to pick up the cooling and guarding plate 60. The transfer robot 18 moves the cooling and guarding plate 60 picked up from the wafer 1 by the cooling and guarding plate arm 56 to the temporary holding chamber 19 so that the cooling and guarding plate 60 can be temporarily stored on a susceptor (not shown) in the temporary holding chamber 19.

Thereafter, the transfer robot 18 picks up the wafer 1 by using the wafer arm 55 and unload same out of the processing chamber 42 of cooling apparatus 40. Then, the transfer robot 18 allows the wafer 1 to be moved from the first cooling chamber 16 to the first cassette chamber 12.

The wafer 1 moved to the first cassette chamber 12 is moved from the wafer arm 55 to the original slot in the original cassette of the first cassette chamber 12. The operation described above may be repeated thereafter.

In the meantime, the wafers 1 on each of which, e.g., a ruthenium film is to be deposited thereon are provided to the second cassette chamber 13. 25 sheets of wafers received in one cassette may be preferably provided. The second CVD chamber 15 and the second cooling chamber 17 are used to deposit a ruthenium film on a wafer 1 received in the cassette of the second cassette chamber 13 in a similar manner as in the Ta₂O₅ deposition and coating process described above. The cooling and guarding plate 60 is also used in the identical manner as in the Ta₂O₅ case described above.

Some of the advantages and the effects of the present embodiment are as follows.

1. Since the surface of the wafer is covered with the cooling and guarding plate during transferring, the surface of the wafer can be protected from being contaminated by foreign materials.

2. Since the wafer is covered with the cooling and guarding plate, the cooling and guarding plate can absorb the heat from the wafer and the wafer can be cooled. Moreover, since the wafer is covered with the cooling and guarding plate during transferring, the wafer can be cooled during the transfer process thereof.

3. Since the wafer is controlled to be slowly pre-cooled before or during the transfer process thereof as described in 2), the wafer may be protected from being warped by a rapid cooling thereof and the cooling time of the wafer in the cooling chamber may be reduced.

4. By cooling the wafer before or during the transfer process thereof, a reaction of any potential contaminants with the wafer after the film forming process may be effectively prevented.

5. Since the radiating fins are installed on the cooling and guarding plate acting as a covering member for covering the surface of the wafer, the heat radiation performance of the cooling and guarding plate may be enhanced and therefore the wafer can be more effectively cooled down during the transfer process thereof.

6. Through the effects described in 1) to 5), the performance and reliability of the CVD apparatus may be improved and the product yield can be also enhanced, which in turn gives rise to the improved quality and reliability of the product.

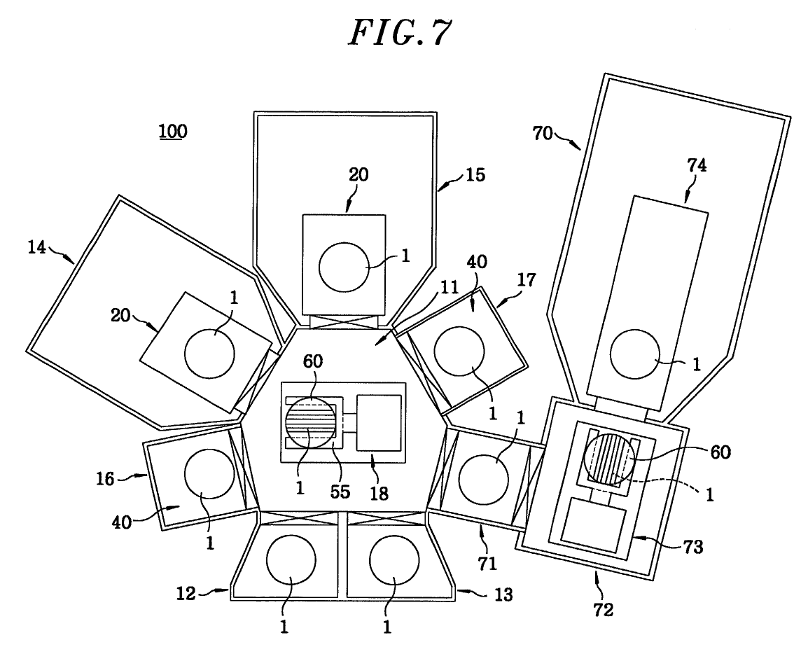

Referring to FIG. 7, there is shown a schematic plan view for illustrating a multi chamber type CVD equipment 100 in accordance with the second preferred embodiment of the present invention.

The CVD equipment 100 of the second embodiment is different from the CVD equipment 10 of the first embodiment in that it is further provided with a cleaning chamber 70. Specifically, a load-lock chamber 71, which is also used as a temporary holding chamber of the cooling and guarding plates 60, is installed between the second cassette chamber 13 and the second cooling chamber 17 as shown in FIG. 7. A transfer chamber 72 is used to connect the load-lock chamber 71 with the cleaning chamber 70. A transfer robot 73 for transferring the wafer 1 between the load-lock chamber 71 and the cleaning chamber 70 is installed in the transfer chamber 72. A gas phase cleaning apparatus 74 for cleaning the wafer 1 by using a gas is installed in the cleaning chamber 70. A single wafer HF vapor cleaning apparatus, an argon aerosol cleaning apparatus, a dry cleaning apparatus or the like can be exemplified as the gas phase cleaning device 74 for cleaning the wafer with a gas. The cleaning apparatus installed in the cleaning chamber 70 may not be necessarily a gas phase cleaning apparatus. A liquid phase or wet cleaning apparatus may be used as the cleaning apparatus in the cleaning chamber 70.

The wafer 1 is cleaned in the cleaning chamber 70. The cleaned wafer 1 is covered with the cooling and guarding plate 60 and then transferred to the first CVD chamber 14 or the second CVD chamber 15. Since the cleaned wafer 1 is temporarily stored in the load-lock chamber 71, the load-lock chamber 71 also functions as the temporary holding chamber 19 of the first embodiment shown in FIG. 1.

Since the wafer 1 is covered with the cooling and guarding plate 60 during the transfer process of wafer from the cleaning chamber 70 to the first CVD chamber 14 or the second CVD chamber 15, the cleaned wafer 1 may be protected from being contaminated by contaminants and, therefore, the quality and reliability of the film formed in the first CVD chamber 14 and the second CVD chamber 15 may be improved.

The present invention is not limited to the embodiments described above and it will be understood by those skilled in the art that various changes and modifications may be made without departing from the spirit and scope of the invention.

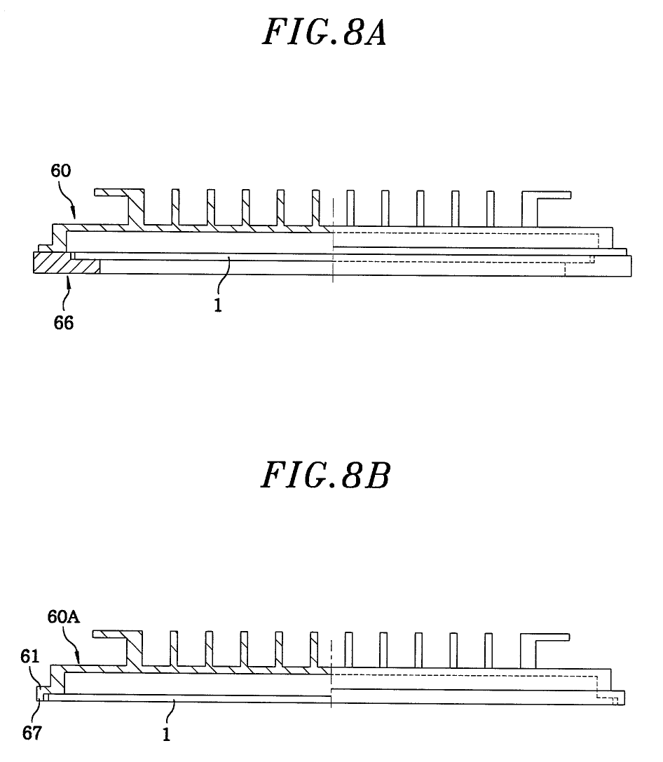

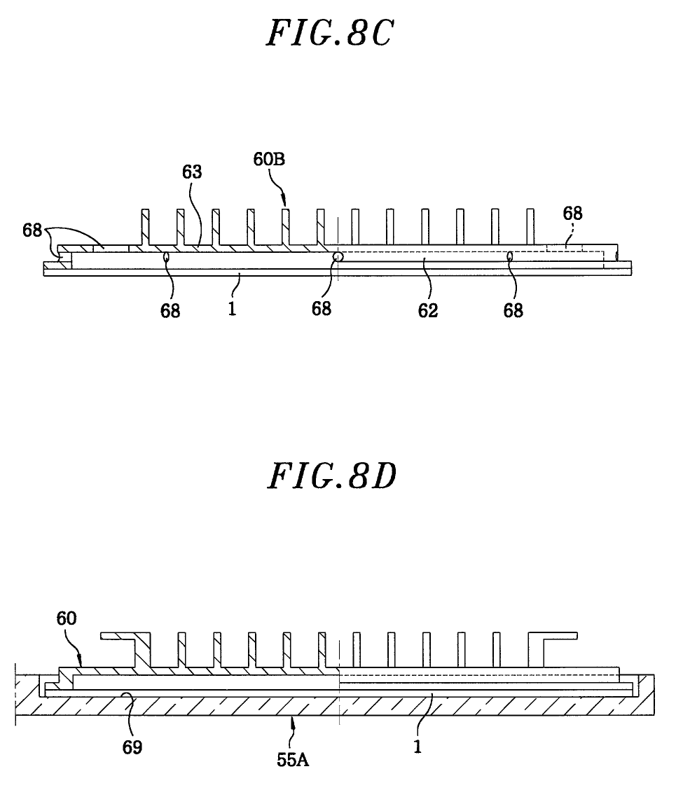

For example, the radiating fins on the cooling and guarding plate may be eliminated if not required when considering the heat radiation performance. Further, the heat capacity of the cooling and guarding plate may be preferably determined according to the required cooling performance. Further, the structure of the cooling and guarding plate serving as a covering member for covering the surface of the substrate may not necessarily limited to the one shown in FIGS. 6A and 6B, but can be configured, for example, as shown in FIGS. 8A to 8D.

As shown in FIG. 8A, the cooling and guarding plate 60 may be supported by a holding member 66 of a ring shape with the L-shape cross section. In other words, the surface of the wafer 1 is covered with the cooling and guarding plate 60 supported on the holding member 66 while the wafer 1 is mounted on the stepped portion of the L-shaped holding member 66. Since the cooling and guarding plate 60 is supported by the holding member 66 without being into direct contact with the wafer 1, the wafer 1 may be protected from being contaminated by contaminants, scratched by the cooling and guarding plate 60 or attached by dusts.

Referring to FIG. 8B, there is shown another cooling and guarding plate 60A having a position determining protrusion 67 for preventing the offset between the cooling and guarding plate 60A and the wafer 1. The position determining protrusion 67 is projected downwards along the outer perimeter of the abutting ring 61 to be coupled with the outer perimeter of the wafer 1.

Referring to FIG. 8C, there is shown still another cooling and guarding plate 60B having a plurality of holding holes 68 instead of the handles 65, wherein the holding holes 68 used to support the cooling and guarding plate 60B by the cooling and guarding plate arm 56 are installed on the support ring 62 and the covering plate 63. The cooling and guarding plate 60B may be transferred by coupling the holding holes 68 with an end portions of the cooling and guarding plate arm 56 or hook portions thereat. The holding holes 68 may be installed on either one of the support ring 62 and the covering plate 63, if necessary, without being installed on both the support ring 62 and the covering plate 63. Even in a case of leaving the handles 65 on the cooling and guarding plate as in FIGS. 8A and 8B to support the cooling and guarding plate arm 56, it may be preferred to have the holding holes 68 on the support ring 62 and/or the covering plate 63. Since the holding holes 68 are used as air ventilation holes in this case, the cooling and guarding plate 60 may be easily removed from the wafer 1.

Referring to FIG. 8D, there is shown a wafer arm 55A having a position determining recess 69, wherein the wafer arm 55A is used to move the cooling and guarding plate 60. Specifically, the position determining recess 69 is formed on an upper surface of the wafer arm wafer arm wafer arm 55A. The position determining recess 69 is a cylindrical hole having a diameter slightly larger than these of the wafer 1 and the cooling and guarding plate 60. After the wafer 1 with the cooling and guarding plate 60 covered thereon is concentrically received in the position determining recess 69, the wafer arm 55A is transferred. Accordingly, the cooling and guarding plate 60 can be prevented from slipping on the wafer 1.

The number of the cooling chambers can be changed adaptively to the number of processing chambers such as the CVD chambers.

The structure of the cooling chambers is not limited to that of the above embodiments, so that it may be modified according to the requirements on the cooling performance and so on.

Even though only the multi chamber CVD equipment has been shown for illustration in the above embodiment, it would be apparent to those skilled in the art that the present invention may be equally applied to other types of semiconductor processing equipment such as a single wafer CVD equipment.

Although the preferred embodiments have been described with respect to the method for manufacturing semiconductor devices, the present invention may be applied to the method for manufacturing LCD as well.

While the invention has been shown and described with respect to the preferred embodiments, it will be understood by those skilled in the art that various changes and modifications may be made without departing from the spirit and scope of the invention as defined in the following claims.

What is claimed is:

1. A substrate processing equipment comprising:
a substrate; and
a covering member for covering a surface of the substrate,
wherein the substrate is transferred with the surface of the substrate covered with the covering member.

2. The equipment of claim 1, further comprising a cleaning chamber for cleaning the substrate and a processing chamber for processing the substrate,
wherein, after the substrate is cleaned, the cleaned substrate is transferred to the processing chamber with the surface of the substrate covered with the covering member.

3. The equipment of claim 1, further comprising a plurality of processing chambers,
wherein the substrate is transferred from one processing chamber to another processing chamber with the surface of the substrate covered with the covering member.

4. A substrate processing equipment comprising:
a substrate; and
a covering member for covering a surface of the substrate,
wherein the substrate is cooled with the surface of the substrate covered with the covering member.

5. A substrate processing equipment having a processing chamber, comprising:
a substrate;
a covering member for covering a surface of the substrate,
wherein after the substrate is processed in the processing chamber, the covering member is inserted into the processing chamber and the surface of the substrate is covered with the covering member.

6. A substrate processing equipment having a processing chamber, comprising:
a substrate;
a covering member for covering a surface of the substrate; and
a holding member for placing the substrate thereon, wherein the holding member has a portion for determining thereon a position of the substrate,
wherein the substrate is taken in and out of the processing chamber with the covering member mounted on the holding member.

7. A method for processing a substrate in an equipment having a processing chamber, comprising the steps of:
processing the substrate in the processing chamber; and
transferring the substrate,
wherein the substrate is transferred in the equipment with a surface thereof covered with the covering member.

8. A covering member comprising:
a covering plate for covering a surface of a substrate; and
a radiating fin, located outside the covering plate, for radiating heat from the substrate.
